(19) United States
(12) Patent Application Publication
(10) Pub. No.: US 2025/0297367 A1
(43) Pub. Date: Sep. 25, 2025

(54) METHOD FOR FORMING CONDUCTIVE LAYER-ATTACHED RESIN BASE MATERIAL

(71) Applicant: Shibaura Machine Co., Ltd., Tokyo (JP)

(72) Inventors: Mitsunori KOKUBO, Numazu (JP); Kazuhiro FUKADA, Numazu (JP); Hiroyuki UEYAMA, Numazu (JP)

(73) Assignee: Shibaura Machine Co., Ltd., Tokyo (JP)

(21) Appl. No.: 18/862,240

(22) PCT Filed: Jun. 8, 2023
(86) PCT No.: PCT/JP2023/021330

§ 371 Date: Nov. 1, 2024

(30) Foreign Application Priority Data
Jun. 17, 2022 (JP) 2022-097819

(51) Int. Cl. C23C 28/00; C23C 14/02; C23C 14/34; C25D 3/38

(52) U.S. Cl. CPC C23C 28/00; C23C 14/022; C23C 14/34; C25D 3/38

(57) ABSTRACT

A method for forming a conductive layer-attached resin base material includes a roughening step, a blasting step, a modification step, a first conductive layer formation step, and a second conductive layer formation step. The roughening step performs roughening treatment on a surface of an insulating resin base material. The blasting step performs blast treatment on the surface of the insulating resin base material on which the roughening treatment has been performed, by dry blasting. The modification step performs surface modification on the surface of the insulating resin base material on which the blast treatment has been performed. The first conductive layer formation step forms a first conductive layer on the insulating resin base material on which the surface modification has been performed. The second conductive layer formation step forms a second conductive layer on the first conductive layer by a wet film formation process.

### TECHNICAL FIELD

An embodiment of the present invention relates to a method for forming a conductive layer-attached resin base material.

### BACKGROUND ART

A technology that forms a conductive layer on an insulating resin base material is known. For example, a method is disclosed in which openings such as via holes are formed in an insulating resin base material, filler or the like that is exposed on the inner wall surfaces of opening portions and likely to detach is removed, and then a conductive layer is formed (see, for example, Patent Literature 1).

Patent Literature 1 discloses a method in which an insulating resin layer with openings formed therein is sequentially subjected to three steps of a first alkali treatment, ultrasonic cleaning treatment, and a second alkali treatment and thereby filler or the like that is exposed on the inner wall surfaces of opening portions and likely to detach due to the formation of openings is removed. Patent Literature 1 discloses that, by forming a conductive layer after the above three steps are sequentially performed, it is attempted to improve adhesion between the insulating resin layer and the conductive layer.

### CITATION LIST

### Patent Literature

Patent Document 1: JP 2021-005624 A

### SUMMARY OF INVENTION

### Problem to be Solved by the Invention

However, in the conventional technology, there has been a case where the adhesion strength between the insulating resin base material and the conductive layer is reduced due to the influence of resin portions or the like that have become brittle due to, in addition to detachment of filler, sparsification by desmearing. Further, in the conventional technology, it is necessary to perform three steps in order to remove filler or the like that is detached or is about to detach, and there has been a case where extension of the process is a problem. That is, in the conventional technology, it has been difficult to achieve both improvement in adhesion strength between the insulating resin base material and the conductive layer and shortening of the process.

The present invention has been made in view of the above, and an object of the present invention is to provide a method for forming a conductive layer-attached resin base material capable of improving the adhesion strength between an insulating resin base material and a conductive layer and shortening the process.

### Means for Solving Problem

A method for forming a conductive layer-attached resin base material according to an embodiment is includes: a roughening step of performing roughening treatment on a surface of an insulating resin base material; a blasting step of performing blast treatment on the surface of the insulating resin base material on which the roughening treatment has been performed, by dry blasting; a modification step of performing surface modification on the surface of the insulating resin base material on which the blast treatment has been performed; a first conductive layer formation step of forming a first conductive layer on the insulating resin base material on which the surface modification has been performed; and a second conductive layer formation step of forming a second conductive layer on the first conductive layer by a wet film formation process.

### BRIEF DESCRIPTION OF DRAWINGS

FIG. 1 is a schematic diagram of an example of a conductive layer-attached resin base material of the present embodiment;

FIG. 2A is a schematic diagram illustrating an example of a method for forming a conductive layer-attached resin base material of the present embodiment;

FIG. 2B is a schematic diagram illustrating the example of the method for forming a conductive layer-attached resin base material of the present embodiment;

FIG. 2C is a schematic diagram illustrating the example of the method for forming a conductive layer-attached resin base material of the present embodiment;

FIG. 2D is a schematic diagram illustrating the example of the method for forming a conductive layer-attached resin base material of the present embodiment;

FIG. 2E is a schematic diagram illustrating the example of the method for forming a conductive layer-attached resin base material of the present embodiment;

FIG. 2F is a schematic diagram illustrating the example of the method for forming a conductive layer-attached resin base material of the present embodiment;

FIG. 3 is a schematic configuration diagram illustrating an example of a configuration of a surface treatment apparatus that performs one-surface film formation; and

FIG. 4 is a top view illustrating an example of a configuration of the interior of a chamber of the surface treatment apparatus of FIG. 3.

### DESCRIPTION OF EMBODIMENTS

Hereinbelow, details of the present embodiment are described with reference to the appended drawings. In the drawings, the same constituent portions are denoted by the same reference numerals, and a repeated description may be omitted.

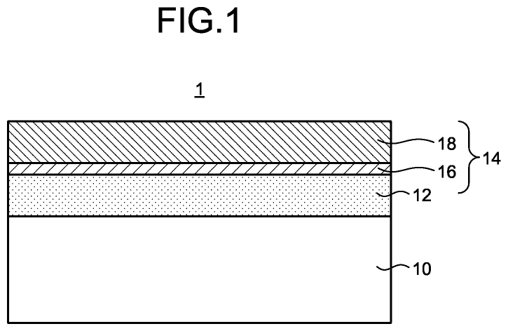

FIG. 1 is a schematic diagram of an example of a conductive layer-attached resin base material 1 of the present embodiment.

The conductive layer-attached resin base material 1 is a stacked body in which an insulating resin base material 12 and a conductive layer 14 are sequentially stacked on a core base material 10.

The core base material 10 is a base material serving as a core of the conductive layer-attached resin base material 1. As the core base material 10, for example, what is called a glass epoxy substrate in which glass cloth is impregnated with an insulating resin such as an epoxy-based resin, or the like can be used. As the core base material 10, also a substrate in which a woven fabric or a nonwoven fabric of glass fiber, carbon fiber, aramid fiber, or the like is impregnated with an epoxy-based resin, etc., or the like may be used. The core base material 10 may also be a stacked body composed of a plurality of layers. For example, the core base material 10 may be a stacked body in which a conductive layer, an insulating layer, a wiring layer, etc. are stacked.

The thickness of the core base material 10 is not limited. The thickness of the core base material 10 may be adjusted according to the object for which the conductive layer-attached resin base material 1 is to be used, etc., as appropriate. In the case where, for example, the conductive layer-attached resin base material 1 is used as part of a wiring board, the thickness of the core base material 10 is, for example, 60 μm or more and 1000 μm or less, or the like.

The insulating resin base material 12 is provided on at least one surface in the thickness direction of the core base material 10. In the present embodiment, a form in which the insulating resin base material 12 is provided on one surface in the thickness direction of the core base material 10 is described as an example. The insulating resin base material 12 may be provided on both surfaces in the thickness direction of the core base material 10.

The insulating resin base material 12 is a resin base material having insulating properties. The insulating resin base material 12 may be any of a substrate shape, a layer shape, a film shape, and a bulk material. In the present embodiment, a form in which the insulating resin base material 12 is in a layer shape is described as an example. A configuration in which the conductive layer-attached resin base material 1 does not includes the core base material 10 may be employed. In this case, the conductive layer-attached resin base material 1 may be made to function as the core base material 10. For example, a configuration in which the core base material 10 is formed of a resin base material having insulating properties, and the conductive layer-attached resin base material 1 and the core base material 10 are molded as the same layer or the same substrate may be employed.

The constituent material of the insulating resin base material 12 needs only to be an insulating resin material, and is not limited. Examples of the constituent material of the insulating resin base material 12 include, as well as epoxy resins widely used as insulating resins, imide resins, phenol formaldehyde resins, novolac resins, melamine resins, polyphenylene ether resins, bismaleimide-triazine resins, siloxane resins, maleimide resins, polyether ether ketone resins, polyetherimide resins, polyethersulfone, and the like. As a constituent material of the insulating resin base material 12, a resin produced by mixing two or more resins selected from these resins at an arbitrary ratio, or the like may be used.

The thickness of the insulating resin base material 12 is not limited. The thickness of the insulating resin base material 12 may be adjusted according to the object for which the conductive layer-attached resin base material 1 is to be used, etc., as appropriate. In the case where, for example, the conductive layer-attached resin base material 1 is used as part of a wiring board, the thickness of the insulating resin base material 12 is, for example, 10 μm or more and 40 μm or less, or the like.

The insulating resin base material 12 may be a configuration containing filler, or may be a configuration free of filler.

The material of filler contained in the insulating resin base material 12 is not limited. Examples of the filler include silica, alumina, glass, cordierite, silicon oxides, barium sulfate, barium carbonate, talc, clay, mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium titanate zirconate, barium zirconate, calcium zirconate, zirconium phosphate, zirconium phosphate tungstate, and the like. Among them, silica is particularly preferable.

The particle size and content amount of filler are not limited. The particle size of filler is, for example, 0.3 μm or more and 4 μm or less, or the like. The content amount of filler contained in the insulating resin base material 12 is, for example, 30 wt % or more and 60 wt % or less, or the like relative to 100 wt % of the insulating resin base material 12.

Vias may be formed in the insulating resin base material 12.

The conductive layer 14 is a layer having conductivity. The conductive layer 14 is a layer in which a second conductive layer 18 is stacked on a first conductive layer 16. The first conductive layer 16 functions as a seed layer for the second conductive layer 18. The second conductive layer 18 is a metal plating layer formed on the first conductive layer 16, which is a seed layer.

The first conductive layer 16 and the second conductive layer 18 need only to be layers having conductivity, and the constituent materials of the first conductive layer 16 and the second conductive layer 18 are not limited. Examples of the first conductive layer 16 and the second conductive layer 18 include Cu, Al, Au, Pt, and Ir, alloys of two or more of them, and the like. The first conductive layer 16 and the second conductive layer 18 are preferably formed of the same metal from the viewpoint of improving adhesion between these layers. For example, the first conductive layer 16 and the second conductive layer 18 are preferably formed of copper (Cu).

Next, a method for forming the conductive layer-attached resin base material 1 of the present embodiment is described in detail.

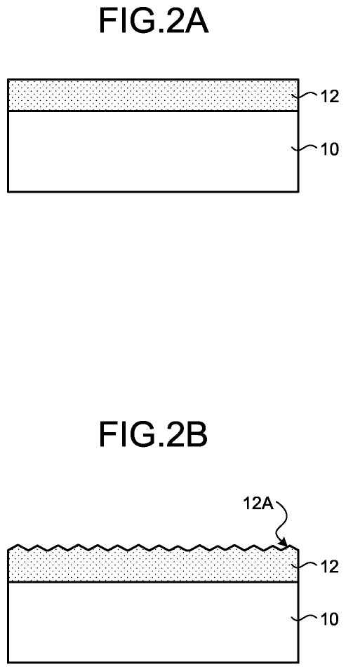

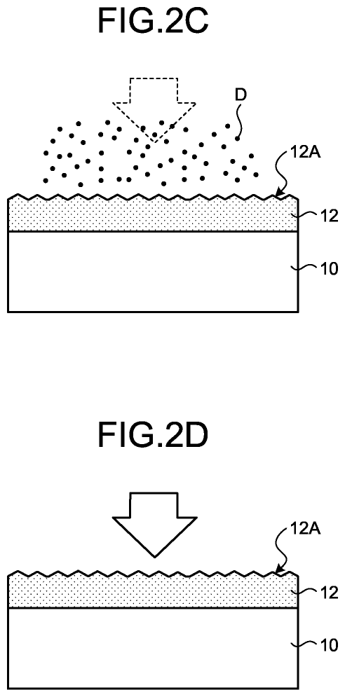

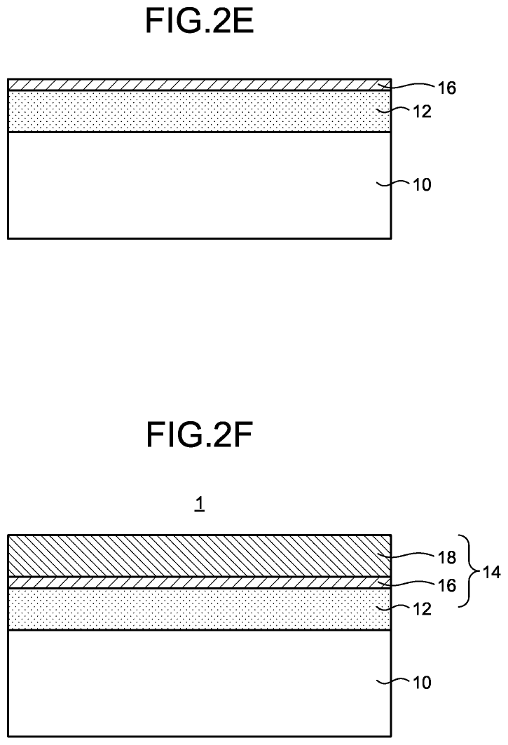

FIGS. 2A to 2F are schematic diagrams illustrating an example of a method for forming the conductive layer-attached resin base material 1 of the present embodiment.

The method for forming the conductive layer-attached resin base material 1 includes a roughening step, a blasting step, a modification step, a first conductive layer formation step, and a second conductive layer formation step.

FIG. 2A is a schematic diagram of a base material in which an insulating resin base material 12 is stacked on a core base material 10. First, a base material in which the insulating resin base material 12 is stacked on the core base material 10 is prepared. As described above, the insulating resin base material 12 may be made to function as the core base material 10, and a base material in which the insulating resin base material 12 and the core base material 10 are integrally configured may be prepared.

FIG. 2B is an explanatory diagram of an example of a roughening step. In the roughening step, a surface 12A of the insulating resin base material 12 is subjected to roughening treatment. As subject to the roughening treatment, the surface 12A of the insulating resin base material 12 enters a roughened state. The roughening treatment needs only to be treatment of roughening the surface 12A of the insulating resin base material 12. The roughening treatment includes formation of openings such as via holes on the surface 12A of the insulating resin base material 12, formation of fine unevenness on the surface 12A, and the like.

For the roughening treatment, either a wet system or a dry system may be used.

Examples of wet roughening treatment include chromic acid etching, permanganic acid etching, organic solvent etching, and the like. The wet roughening treatment may be performed by immersing the surface 12A of the insulating resin base material 12 for a predetermined period of time in a solution such as a chromic acid solution, a permanganic acid solution, or an organic solvent heated to a predetermined temperature. The predetermined temperature of roughening treatment is, for example, 60° C. to 80° C., or the like, but is not limited to this temperature range. The predetermined period of time for immersion is, for example, 10 minutes to 30 minutes, or the like, but is not limited to this range.

Examples of dry roughening treatment include plasma treatment, ultraviolet irradiation, and the like. As reaction gas used as plasma gas of plasma treatment, for example, oxygen, argon, hydrogen, nitrogen, or the like may be used alone or in a mixed state.

Examples of roughening treatment using plasma include dry treatment based on a microwave plasma system and dry treatment based on a heat assist system. The microwave plasma system can reduce the heat load on the insulating resin base material 12.

FIG. 2C is an explanatory diagram of an example of a blasting step. The blasting step is a step of performing blast treatment on the surface 12A of the insulating resin base material 12 on which the roughening treatment has been performed, by dry blasting.

The dry blasting is a non-wet blasting method, and examples include dry ice blasting using dry ice particles D, air blasting using compressed air, and the like. Sandblasting using an abrasive material causes the abrasive material to remain on the surface, and is not preferable. When dry ice blasting using dry ice particles D is used for the blasting step, no abrasive material remains. An abrasive material that changes to gas after collision in this way is preferable because it does not remain on the surface. FIG. 2C illustrates, as an example, dry blasting using dry ice particles D.

The particle size of the dry ice particle D is not limited, but is preferably, for example, in the range of 1 μm or more and 200 μm or less. The particle size of the dry ice particle D can be measured by, for example, photographing with a high-speed camera or the like.

The flow velocity of dry ice particles D is not limited, but is preferably, for example, in the range of 300 m/sec or more and 400 m/sec or less. The flow velocity of dry ice particles D can be measured with an anemometer.

The nozzle pressure of dry ice blasting is not limited, but is preferably, for example, in the range of 0.3 MPa or more and 0.7 MPa or less.

A known apparatus may be used as a blasting apparatus used for dry ice blasting or air blasting.

The surface 12A of the insulating resin base material 12 is roughened by the roughening step performed before the blasting step. By the surface 12A being roughened, the resin of the surface 12A of the insulating resin base material 12 is weakened, and thus the adhesion strength is reduced. Further, in the case where filler is contained in the insulating resin base material 12, in addition to weakening of the resin surface, part of the filler is exposed on the surface 12A in an about-to-detach state. A first conductive layer 16 that is formed on a resin layer weakened by roughening would be likely to peel off.

In the blasting step, the surface 12A of the insulating resin base material 12 is subjected to blast treatment by dry blasting. By performing blast treatment, the weak layer formed on the surface of the insulating resin base material 12 is removed from the surface 12A. Thus, a first conductive layer 16 can be firmly formed on the surface 12A in a hard-to-peel manner.

The inventor observed, with a SEM image, that even in a substrate made only of resin free of filler, the surface was roughened and made easy to peel due to the roughening step. The inventor observed, likewise with a SEM image, that when blast treatment was performed on such a surface, the surface was smoothed and entered a hard-to-peel state.

In the blasting step of the present embodiment, since the surface 12A of the insulating resin base material 12 is subjected to blast treatment by dry blasting, dry cleaning can be performed without impregnating the surface 12A of the insulating resin base material 12 with moisture.

Further, in the case where dry ice blasting using dry ice particles D is performed as the blasting step, it is surmised that the following effects can be obtained. Specifically, by being sprayed onto the surface 12A of the insulating resin base material 12, the dry ice particles D can remove the weak layer formed on the surface 12A. The weak layer and filler that is about to detach are removed by physical collision of dry ice particles D and volume expansion based on sublimation of dry ice. Thus, it is presumed that the weak layer formed on the surface 12A of the insulating resin base material 12 is effectively removed in a short time by performing dry blasting using dry ice particles D.

FIG. 2D is an explanatory diagram of an example of a modification step. The modification step is a step of performing surface modification on the surface 12A of the insulating resin base material 12 on which the blast treatment has been performed.

In the present embodiment, the “surface modification” is a treatment that cuts molecular chains present on the surface 12A of the insulating resin base material 12 and generates functional groups such as hydroxy groups, carboxy groups, and formyl groups. Examples of surface modification include modification treatment using plasma treatment, ultraviolet irradiation treatment, UV (ultraviolet) ozone treatment, fine bubble ozone water treatment, electrolytic sulfuric acid treatment, or the like. The electrolytic sulfuric acid is a solution produced by electrolysis of sulfuric acid. The modification treatment may use only one of these treatments, or may use two or more of these treatments and sequentially perform them.

In the case where plasma treatment is used as the modification step, the modification step preferably performs surface modification on the surface of the insulating resin base material 12 by a first plasma treatment with an oxidizing gas containing 95% or more oxygen and a second plasma treatment with a reducing gas containing 1% or more H₂ gas after the first plasma treatment.

The treatment conditions of modification treatment may be set according to the method of modification treatment used, the type of the insulating resin base material 12, etc., as appropriate.

FIG. 2E is an explanatory diagram of an example of a first conductive layer formation step. The first conductive layer formation step is a step of forming a first conductive layer 16 on the surface 12A of the insulating resin base material 12 on which the surface modification has been performed.

For the formation of the first conductive layer 16 in the first conductive layer formation step, a film formation process of either a wet system or a dry system may be used.

Examples of the film formation process of the first conductive layer 16 based on a dry system, that is, a dry film formation process include sputtering of a conductive material serving as a target. By performing film formation of the first conductive layer 16 on the insulating resin base material 12 by a dry film formation process, a step of giving a catalyst such as Pd to the surface 12A in advance before formation of the first conductive layer 16 can be omitted. That is, the process can be shortened.

Examples of the film formation process of the first conductive layer 16 based on a wet system, that is, a wet film formation process include electroless plating in which film formation is performed by immersing the surface 12A in a plating solution.

FIG. 2F is an explanatory diagram of an example of a second conductive layer formation step. The second conductive layer formation step is a step of forming a second conductive layer 18 on the first conductive layer 16 by a wet film formation process.

Examples of the wet film formation process used for the formation of the second conductive layer 18 include a method of using electrolytic plating to form a second conductive layer 18 that is an electrolytic plating layer.

A conductive layer-attached resin base material 1 is formed through the roughening step, the blasting step, the modification step, the first conductive layer formation step, and the second conductive layer formation step described using FIGS. 2A to 2F in this order.

The conductive layer-attached resin base material 1 made through these steps may be further subjected to treatments such as a firing step (annealing) and removal of part of the first conductive layer 16 to form a wiring board, an IC (integrated circuit) chip, or the like.

Specifically, a firing step in which a stacked body formed through the roughening step, the blasting step, the modification step, the first conductive layer formation step, and the second conductive layer formation step in this order is heated at a temperature lower than the glass transition point of the insulating resin base material 12 may be further performed.

By further performing the firing step, the adhesion strength between the insulating resin base material 12 and the conductive layer 14 can be further improved.

The interval (time) between consecutive ones of the roughening step, the blasting step, the modification step, the first conductive layer formation step, the second conductive layer formation step, and the firing step described above is not limited. However, the interval between consecutive ones of these steps preferably satisfies the following conditions.

Specifically, the blasting step is preferably started within 48 hours from the end of the roughening step. The modification step is preferably started within 48 hours from the end of the blasting step. The second conductive layer formation step is preferably started within 12 hours from the end of the first conductive layer formation step. The firing step is preferably started within 6 hours from the end of the second conductive layer formation step.

By at least one of the intervals between consecutive steps satisfying the above conditions, the adhesion strength between the insulating resin base material 12 and the conductive layer 14 can be further improved, and the process can be further shortened.

As described hereinabove, a method for forming the conductive layer-attached resin base material 1 of the present embodiment includes a roughening step, a blasting step, a modification step, a first conductive layer formation step, and a second conductive layer formation step. The roughening step performs roughening treatment on a surface 12A of an insulating resin base material 12. The blasting step performs blast treatment on the surface 12A of the insulating resin base material 12 on which the roughening-treatment has been performed, by dry blasting. The modification step performs surface modification on the surface of the insulating resin base material 12 on which the blast treatment has been performed. The first conductive layer formation step forms a first conductive layer 16 on the insulating resin base material 12 on which the surface modification has been performed. The second conductive layer formation step forms a second conductive layer 18 on the first conductive layer 16 by a wet film formation process.

Thus, in the method for forming the conductive layer-attached resin base material 1 of the present embodiment, the surface 12A of the insulating resin base material 12 is roughened by the roughening step. By the surface 12A being roughened, a state where resin powder of the insulating resin base material 12 adheres to the surface 12A of the insulating resin base material 12 is caused. Further, in the case where filler is contained in the insulating resin base material 12, a state where part of the filler adheres to the surface 12A of the surface 12A is caused.

Thus, in the blasting step, the surface 12A of the insulating resin base material 12 is subjected to blast treatment by dry blasting. By performing blast treatment, a weak layer and minute foreign matters such as filler generated by sparsification of the insulating resin base material 12 are removed from the surface 12A. Further, in the blasting step, since the surface 12A of the insulating resin base material 12 is subjected to blast treatment by dry blasting, dry cleaning can be performed in a short time without impregnating the surface 12A of the insulating resin base material 12 with moisture.

Then, by the first conductive layer 16 and the second conductive layer 18 being formed on the insulating resin base material 12 on which the blast treatment has been performed, a situation where a weak layer and minute foreign matters such as filler generated by sparsification are present between the insulating resin base material 12 and the conductive layer 14 is suppressed. Thus, in the method for forming the conductive layer-attached resin base material 1 of the present embodiment, the adhesion strength between the insulating resin base material 12 and the conductive layer 14 can be improved.

Further, since the conductive layer 14 is formed on the roughened surface 12A, the adhesion strength between the insulating resin base material 12 and the conductive layer 14 can be improved.

Here, in the conventional technology, it has been the case that the removal of minute foreign matters such as filler is performed by three steps of a first alkali treatment, ultrasonic cleaning treatment, and a second alkali treatment. On the other hand, in the present embodiment, minute foreign matters of the surface 12A are removed by one step of a blasting step by dry blasting. Thus, in the method for forming the conductive layer-attached resin base material 1 of the present embodiment, the process can be shortened.

Therefore, the method for forming the conductive layer-attached resin base material 1 of the present embodiment can improve the adhesion strength between the insulating resin base material 12 and the conductive layer 14, and can shorten the process.

As described above, in the case where plasma treatment is used as the modification step, the modification step preferably performs surface modification on the surface of the insulating resin base material 12 by a first plasma treatment with an oxidizing gas containing 95% or more oxygen and a second plasma treatment with a reducing gas containing 1% or more H₂ gas after the first plasma treatment.

By performing, as the modification step, the second plasma treatment after the first plasma treatment, the adhesion strength between the insulating resin base material 12 and the conductive layer 14 can be further improved.

Further, by performing, as the modification step, the second plasma treatment after the first plasma treatment, even in the case where a fully cured (completely cured) insulating resin base material 12 is used, some reducibility can be imparted to the surface of the insulating resin base material 12. Therefore, for example, by activating the conductive layer-attached resin base material 1 by annealing, Cu—O bonding is induced at the interface between the surface of the insulating resin base material 12 and the conductive layer 14. Thus, even in the case where a fully cured insulating resin base material 12 is used, the adhesion strength between the insulating resin base material 12 and the conductive layer 14 can be further improved. Further, by forming the conductive layer 14 by using a fully cured insulating resin base material 12, wiring patterning of about several micrometers using the conductive layer 14 can be performed with high accuracy.

As described above, vias may be formed in the insulating resin base material 12. Also in the via formation region in the insulating resin base material 12, similarly to the above, the roughening step, the blasting step, and the modification step are performed, and a conductive layer 14 is formed. Thus, likewise also in the case where electrolytic plating is used as the conductive layer 14, the adhesion strength between the conductive layer 14, which is plating, and the insulating resin base material 12 can be improved, and the process can be shortened.

Among the roughening step, the blasting step, the modification step, the first conductive layer formation step, and the second conductive layer formation step in the method for forming the conductive layer-attached resin base material 1 of the present embodiment, two or more consecutive steps that are treatments based on a dry system are preferably performed in one vacuum environment.

For example, it is preferable that treatment based on a dry system be used for the modification step and the first conductive layer formation step and these steps be performed in one vacuum environment. Specifically, plasma treatment is used for surface modification of the modification step, and sputtering, which is a dry film formation process, is used for the first conductive layer formation step. The surface modification of the insulating resin base material 12 and the formation of the first conductive layer 16 may be continuously performed using an apparatus that performs the modification step and the first conductive layer formation step in one chamber.

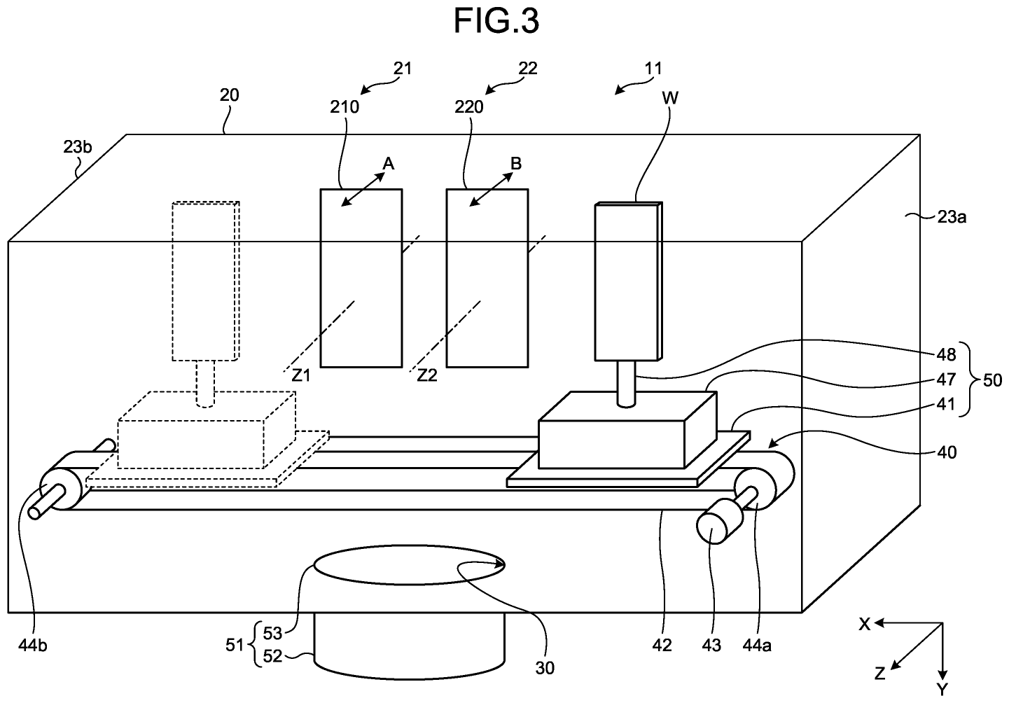

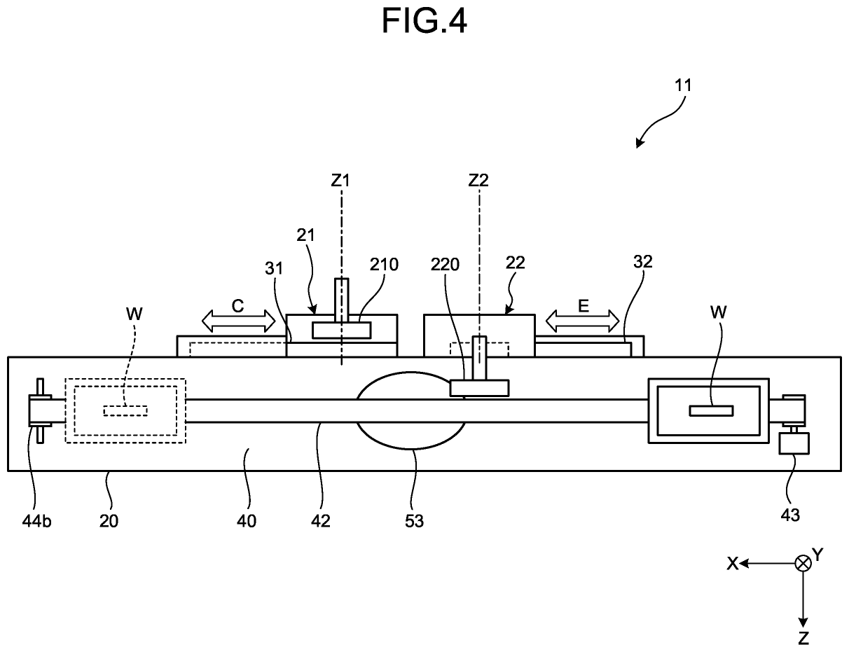

FIGS. 3 and 4 are schematic diagrams of an example of a surface treatment apparatus 11. The surface treatment apparatus 11 is an example of an apparatus that performs a modifying process and a first conductive layer forming process in a single chamber.

FIG. 3 illustrates an example of a configuration of the surface treatment apparatus 11 that performs one-surface film formation. FIG. 4 is a top view illustrating an example of a configuration of the interior of a chamber of the surface treatment apparatus 11 of FIG. 3.

The surface treatment apparatus 011 includes a workpiece mounting unit 50, a workpiece conveyance unit 40, a plasma electrode 210, and a sputtering electrode 220, which are enclosed in a chamber 20.

The chamber 20 is a sealed reaction vessel in which surface treatment is performed on the workpiece W housed therein. The chamber 20 has a rectangular parallelepiped shape having the longitudinal direction along the X-axis direction in the XYZ coordinate system illustrated in FIG. 3.

The workpiece mounting unit 50 holds the workpiece W thereon in a state where it is kept substantially standing along the Y-axis. The workpiece mounting unit 50 includes a movement stage 41, an attachment stage 47, and an attachment shaft 48.

The movement stage 41 is a pedestal on which the workpiece W is set. The movement stage 41 is conveyed along the X-axis by the workpiece conveyance unit 40. The attachment stage 47 is a member that is installed on the movement stage 41 and serves as a base to which the workpiece W is attached. The attachment shaft 48 supports the workpiece W on the attachment stage 47.

The workpiece conveyance unit 40 conveys the workpiece W mounted on the workpiece mounting unit 50 along the longitudinal direction of the chamber 20 (the X-axis). The workpiece conveyance unit 40 is a single-axis movement table driven by a conveyance motor 43. Specifically, the workpiece conveyance unit 40 uses the rotational driving force of the conveyance motor 43 to convey, along the X-axis, the movement stage 41 fixed to a timing belt 42 stretched between two pulleys 44a and 44b. The workpiece W is mounted on the movement stage 41 via the attachment stage 47 and the attachment shaft 48. Therefore, the workpiece W is conveyed along the X-axis by the workpiece conveyance unit 40.

A plasma treatment apparatus 21 and a sputtering apparatus 22 are installed on one side surface of the chamber 20 along the XY plane.

The plasma treatment apparatus 21 irradiates the workpiece W with plasma generated by the plasma electrode 210, and thereby performs surface treatment of the workpiece W. The plasma electrode 210 is movable along an axis Z1 parallel to the Z-axis, that is, in the direction of arrow A. Thus, more uniform film formation treatment can be performed by setting the spacing between the workpiece W and the plasma electrode 210 to an optimum value.

The sputtering apparatus 22 performs sputtering by ejecting atoms used for film formation from a target placed on the sputtering electrode 220 and causing the ejected atoms to adhere to a surface of the workpiece W. The sputtering electrode 220 is movable along an axis Z2 parallel to the Z-axis, that is, in the direction of arrow B. Thus, more uniform film formation treatment can be performed by setting the spacing between the workpiece W and the sputtering electrode 220 to an optimum value.

An exhaust device 51 is installed on the bottom surface of the chamber 20. The exhaust device 51 reduces the pressure of the interior of the chamber 20 into a vacuum state. Further, the exhaust device 51 discharges gas (reaction gas) filling the interior of the chamber 20 due to surface treatment. The exhaust device 51 includes a pump unit 52 and a lifting valve 53. The pump unit 52 is attached to the bottom surface of the chamber 20, and adjusts the pressure of the interior of the chamber 20 and discharges gas filling the interior of the chamber 20 due to an operation of the plasma treatment apparatus 21 or the sputtering apparatus 22. The pump unit 52 is configured using, for example, a rotary pump or a turbomolecular pump. The lifting valve 53 moves between, for example, a state where it is in contact with the bottom surface of the chamber 20 and a state where it has moved on the negative side of the Y-axis, and thereby opens an opening 30 formed in the bottom surface of the chamber 20 to the atmosphere.

Both side surfaces spreading along the YZ plane of the chamber 20 include opening/closing doors 23a and 23b. The opening/closing doors 23a and 23b can be opened and closed by a hinge mechanism or a slide mechanism. An operator of the surface treatment apparatus 11 opens and closes the opening/closing doors 23a and 23b to set the workpiece W and take out the workpiece W for which surface treatment is completed.

The surface treatment apparatus 11 further includes a cooling device, a control device, a power supply device, a gas supply device, an operating panel, etc., but illustration of them is omitted for simplicity of description. The cooling device generates cooling water that cools equipment, a power source, etc. The control device controls the entire surface treatment apparatus 11. The power supply device accommodates power to be supplied to each part of the surface treatment apparatus 11. The gas supply device supplies film-forming gas and reaction gas to the chamber 20. The operating panel accepts an operating instruction to the surface treatment apparatus 11. Further, the operating panel has a function of displaying an operating state of the surface treatment apparatus 11.

The chamber 20 includes a shutter 31 and a shutter 32 illustrated in FIG. 4. The shutter 31 moves along arrow C. The shutter 31 moves on the positive side of the X-axis to expose the plasma electrode 210 when performing plasma treatment on the workpiece W. Further, the shutter 31 moves on the negative side of the X-axis to house the plasma electrode 210 when performing sputtering treatment on the workpiece W. Thereby, contamination of an electrode that is not used is prevented.

The shutter 32 moves along arrow E. The shutter 32 moves on the negative side of the X-axis to expose the sputtering electrode 220 when performing sputtering treatment on the workpiece W. Further, the shutter 32 moves toward the positive side of the X-axis to house the sputtering electrode 220 when performing plasma treatment on the workpiece W. Thereby, contamination of an electrode that is not used is prevented.

It is desirable that, during film formation, the plasma electrode 210 not be moved along axis Z1 and the sputtering electrode 220 not be moved along axis Z2; however, the amounts of feeding in the axis Z1 direction and the axis Z2 direction may be changed according to the degree of vacuum of the interior of the chamber 20, the gas flow rate, the conveyance speed of the workpiece W, the power, the voltage value, the current value, the discharge state, the temperature of the interior of the chamber 20, etc., as appropriate. Thereby, more uniform film formation processing can be performed. Further, the conveyance speed of the workpiece W may be changed according to the values of the parameters mentioned above.

In the present embodiment, the insulating resin base material 12 on which the roughening-treatment and the blast-treatment have been performed is used as a workpiece W. Then, the insulating resin base material 12, which is the workpiece W, is subjected to plasma treatment by the plasma treatment apparatus 21, and thereby the surface modification is performed thereon. Then, the insulating resin base material 12, which is the workpiece W on which the surface modification has been performed, is subjected to sputtering by the sputtering apparatus 22, and thereby a first conductive layer 16 is formed.

In this manner, the modification step and the first conductive layer formation step are performed in one chamber 20 in a vacuum state by using the surface treatment apparatus 11 or the like. In this case, during execution of the modification step and the first conductive layer formation step, exposure of the insulating resin base material 12 to the atmosphere is suppressed. Thus, the adhesion strength between the insulating resin base material 12 and the first conductive layer 16 can be improved more, and the process can be further shortened. That is, it is preferable that the modification step be plasma treatment and the first conductive layer formation step be sputtering, the insulating resin base material 12 be placed in a chamber, and the modification step and the first conductive layer formation step be continuously performed without exposing the insulating resin base material 12 to the atmosphere.

### EXAMPLES

The present invention will now be more specifically described using Examples. However, the present invention is not limited to the following Examples.

### Examples 1 and 2

A base material A that is a common build-up film for semiconductor package substrates (containing filler of SiO₂ in an epoxy-based resin) was prepared as an insulating resin base material 12 stacked on a core base material 10. The size of the insulating resin base material 12 was 50 mm in length×50 mm in width×0.8 mm in thickness.

A surface 12A of the insulating resin base material 12 was subjected to wet roughening treatment (a roughening step). In the roughening step, the following treatment was performed. Swelling treatment (60° C., 5 min), permanganic acid treatment (80° C., 20 min), reduction treatment (40° C., 5 min), and drying treatment (80° C., 15 min).

Next, using a blasting apparatus manufactured by Air Water Inc., product name: QuickSnow (registered trademark), the surface 12A of the insulating resin base material 12 on which the roughening treatment had been performed was subjected to dry ice blasting (a blasting step). As conditions for the dry ice blasting, dry ice blasting was performed while the particle size of the dry ice particle D was set to 10 μm, the nozzle pressure was set to about 0.1 to 0.5 MPa, and the insulating resin base material was moved at a speed of 10 mm/sec.

Next, the surface 12A of the insulating resin base material 12 on which the blast treatment had been performed was subjected to surface modification by plasma treatment (a modification step). As conditions for the plasma treatment for surface modification, the input power was set to 3.8 kW, O₂ gas (gas flow rate: 3000 sccm) was used, the conveyance speed was set to 324 mm/min, and the treatment time per unit area was set to 30 sec.

Next, a first conductive layer 16 was formed on the surface 12A of the insulating resin base material 12 on which the surface modification has been performed, by sputtering (a first conductive layer formation step). As sputtering conditions, after the interior of the chamber was evacuated, Ar gas was introduced until the gas pressure reached 0.3 Pa, and the input power was set to 45 kW and the film formation time was set to 10 sec; thus, a first conductive layer 16 having a thickness of 300 μm was formed.

Next, a second conductive layer 18 was formed on the first conductive layer 16 by electrolytic plating (a second conductive layer formation step). A copper sulfate plating solution (manufactured by JCU Corporation, product name: CU-BRITE 21 (registered trademark)) was used as a plating solution used for the electrolytic plating; a state of a current density (ASD, ampere per square decimeter, A/cm²) of 1 ASD was maintained for one minute, and then a state of 3 ASD was maintained for three minutes. By these treatments, a second conductive layer 18 having a thickness of about 25 μm was formed on the first conductive layer 16.

Then, a conductive layer-attached resin base material 1 produced by a process in which a conductive layer 14 composed of the first conductive layer 16 and the second conductive layer 18 was formed on the insulating resin base material 12 was subjected to annealing treatment (a firing step) at 200° C. for 60 minutes by using a forced convection oven (manufactured by Yamato Scientific Co., Ltd), and then natural cooling was performed; thus, a conductive layer-attached resin base material 1 was obtained.

The blasting step was started 48 hours after the end of the roughening step. The modification step was started 48 hours after the end of the blasting step. The second conductive layer formation step was started 12 hours after the end of the first conductive layer formation step. The firing step was started one hour after the end of the second conductive layer formation step.

The steps from the roughening step to the annealing treatment described above were performed for each of two samples, i.e., insulating resin base materials 12 (common build-up films for semiconductor packages), and two conductive layer-attached resin base materials 1 were produced as conductive layer-attached resin base materials 1 of Examples 1 and 2.

For the thickness of the conductive layer 14 in the conductive layer-attached resin base material 1 of Example 1, the maximum thickness was 25 μm, and the minimum thickness was 22 μm. For the thickness of the conductive layer 14 in the conductive layer-attached resin base material 1 of Example 2, the maximum thickness was 24 μm, and the minimum thickness was 20 μm.

### Comparative Examples 1 and 2

Each of two samples, insulating resin base materials 12, was subjected to the same steps as in Examples 1 and 2 above except that a blasting step was not performed in the process of Examples 1 and 2, and thereby a comparative conductive layer-attached resin base material of each of Comparative Examples 1 and 2 was produced.

For the thickness of the conductive layer 14 in the comparative conductive layer-attached resin base material of Comparative Example 1, the maximum thickness was 32 μm, and the minimum thickness was 29 μm. For the thickness of the conductive layer 14 in the comparative conductive layer-attached resin base material of Comparative Example 2, the maximum thickness was 32 μm, and the minimum thickness was 30 μm.

### Example 3

A base material A that is a common build-up film for semiconductor packages was prepared as an insulating resin base material 12 stacked on a core base material 10. The size of the insulating resin base material 12 was 50 mm in length×50 mm in width×0.8 mm in thickness.

A surface 12A of the insulating resin base material 12 was subjected to dry roughening treatment (a roughening step). Specifically, a plasma desmearing apparatus (manufactured by Nissin Inc., product name: M120 W-Y1) was used to perform roughening treatment with micro plasma waves having an excitation frequency of 2.45 GHz. Then, pure water was used to perform ultrasonic cleaning at 33 kHz for five minutes. Further, washing was performed with running pure water, then N₂ blowing was performed, and then drying was performed at 80° C. for 60 minutes.

Next, using the same blasting apparatus as in Example 1, the surface 12A of the insulating resin base material 12 on which the roughening treatment had been performed was subjected to dry ice blasting under the same blasting conditions as in Example 1 (a blasting step).

Next, the surface 12A of the insulating resin base material 12 on which the blast treatment had been performed was subjected to surface modification by plasma treatment (a modification step). Then, a first conductive layer 16 was formed on the surface 12A of the insulating resin base material 12 on which the surface modification has been performed, by sputtering (a first conductive layer formation step).

In Example 3, the modification step and the first conductive layer formation step were performed using a surface treatment apparatus that performs both-surface film formation, which is improved from the surface treatment apparatus 11 illustrated in FIGS. 3 and 4 that performs one-surface film formation. The surface treatment apparatus 11 illustrated in FIGS. 3 and 4 is a configuration of one-surface film formation in which a plasma treatment apparatus 21 and a sputtering apparatus 22 are provided only on one side in a direction (the Z-axis direction) intersecting the conveyance direction of the workpiece W (the X-axis direction). The surface treatment apparatus that performs both-surface film formation is a configuration in which plasma treatment apparatuses 21 and sputtering apparatuses 22 are provided on both sides in a direction (the Z-axis direction) intersecting the conveyance direction of the workpiece W (the X-axis direction). Otherwise, the surface treatment apparatus that performs both-surface film formation is a similar configuration to the surface treatment apparatus 11 illustrated in FIGS. 3 and 4.

The dimensions of the chamber 20 of the surface treatment apparatus used in Example 3 that performed both-surface film formation were 2,200 mm×1,045 mm×195 mm, and the capacity of the chamber 20 was 450 L.

The interior of the chamber 20 was evacuated; then, using a plasma treatment apparatus 21 provided on one side in a direction (the Z-axis direction) intersecting the conveyance direction of the workpiece W (the X-axis direction), the surface 12A of the insulating resin base material 12, the workpiece W, was subjected to plasma treatment (a first plasma treatment) while the input power was set to 2.5 kW, Ar/H₂ gas (gas flow rate: 3000 sccm) was used, the conveyance speed in the X-axis direction was set to 328 mm/min, and the treatment time was set to 30 sec. In the first plasma treatment, the insulating resin base material 12, the workpiece W, was conveyed from one end side to the other end side in the X-axis direction in the chamber 20.

Next, using a plasma treatment apparatus 21 provided on the other side in a direction (the Z-axis direction) intersecting the conveyance direction of the workpiece W (the X-axis direction), the surface 12A of the insulating resin base material 12, the workpiece W, was subjected to plasma treatment (a second plasma treatment) while the input power was set to 3.8 kW, O₂ gas (gas flow rate: 180 sccm) and Ar gas (gas flow rate: 150 sccm) were used, the conveyance speed in the X-axis direction was set to 328 mm/min, and the treatment time was set to 30 sec. In the second plasma treatment, the insulating resin base material 12, the workpiece W, was conveyed in the opposite direction to that in the first plasma treatment, that is, from the other end side to the one end side in the X-axis direction in the chamber 20.

Further, the insulating resin base material 12 on which the surface modification had been performed by the first plasma treatment and the second plasma treatment was conveyed to a position facing the sputtering apparatus 22 in the chamber 20, and a first conductive layer 16 of copper having a film thickness of 300 nm was formed by the sputtering apparatus 22 under the conditions of an input power of 55 kW and Ar gas (gas flow rate: 150 sccm) (a first conductive layer formation step).

Then, a second conductive layer formation step and annealing treatment were performed in a similar manner to Example 1 above, and thereby a conductive layer-attached resin base material 1 of Example 3 was obtained.

For the thickness of the conductive layer 14 in the conductive layer-attached resin base material 1 of Example 3, the maximum thickness was 24 μm, and the minimum thickness was 20 μm.

### Comparative Examples 3 and 4

Each of two samples, insulating resin base materials 12, was subjected to the same steps as in Example 3 above except that a blasting step was not performed in the process of Example 3, and thereby a comparative conductive layer-attached resin base material of each of Comparative Examples 3 and 4 was produced.

For the thickness of the conductive layer 14 in the comparative conductive layer-attached resin base material of each of Comparative Examples 3 and 4, the maximum thickness was 23 μm, and the minimum thickness was 20 μm.

### Examples 4 to 6

A base material B that is a common build-up film for semiconductor package substrates (containing filler of SiO₂ in an epoxy-based resin) was prepared as an insulating resin base material 12 stacked on a core base material 10. The size of the insulating resin base material 12 was 50 mm in length×50 mm in width×0.8 mm in thickness.

A surface 12A of the insulating resin base material 12 was subjected to roughening treatment in a similar manner to Example 1 under the same conditions as in Example 1 (a roughening step).

Next, using a blasting apparatus manufactured by Air Water Inc., product name: QuickSnow (registered trademark), the surface 12A of the insulating resin base material 12 on which the roughening treatment had been performed was subjected to dry ice blasting (a blasting step). As conditions for the dry ice blasting, dry ice blasting was performed while the particle size of the dry ice particle D was set to 10 μm, the nozzle pressure was set as follows, and the insulating resin base material was moved at a speed of 10 mm/sec. For the nozzle pressure, Example 4 used a nozzle pressure of 0.2 to 0.3 MPa (weak), Example 5 used a nozzle pressure of about 0.1 to 0.5 MPa (standard) similarly to Example 1, and Example 6 used a nozzle pressure of 0.3 to 0.4 MPa.

Next, the surface 12A of the insulating resin base material 12 on which the blast treatment had been performed was subjected to surface modification by plasma treatment (a modification step). Specifically, the surface 12A of the insulating resin base material 12 was subjected to a first plasma treatment with an oxidizing gas containing 95% or more oxygen and a second plasma treatment with a reducing gas containing 1% or more H₂ gas after the first plasma treatment, and thereby the surface modification was performed on the surface of the insulating resin base material 12. As conditions for the first plasma treatment, the input power was set to 2.5 kW, 02 gas (gas flow rate: 3000 sccm) was used, the conveyance speed was set to 955 mm/min, the oxygen concentration was set to 95%, and the treatment time per unit area was set to 20 sec. As conditions for the second plasma treatment, the input power was set to 3.8 kW, the ratio between Ar₂ gas and hydrogen gas was set to a gas flow rate: Ar/H₂=800 sccm), the conveyance speed was set to 490 mm/min, the H₂ gas concentration was set to 5%, and the treatment time per unit area was set to 40 sec.

Next, a first conductive layer 16 having a thickness of 300 μm was formed on the surface 12A of the insulating resin base material 12 on which the surface modification has been performed, by sputtering in a similar manner to Example 1 under the same conditions as in Example 1 (a first conductive layer formation step). Then, a second conductive layer 18 having a thickness of about 25 μm was formed on the first conductive layer 16 in a similar manner to Example 1 under the same conditions as in Example 1 (a second conductive layer formation step). Then, a conductive layer-attached resin base material 1 produced by a process in which a conductive layer 14 composed of the first conductive layer 16 and the second conductive layer 18 was formed on the insulating resin base material 12 was subjected to annealing treatment (a firing step) at 200° C. for 60 minutes by using a forced convection oven (manufactured by Yamato Scientific Co., Ltd), and then natural cooling was performed; thus, a conductive layer-attached resin base material 1 was obtained.

In Examples 4 to 6, the blasting step was started 48 hours after the end of the roughening step. The modification step was started 48 hours after the end of the blasting step. The second conductive layer formation step was started 12 hours after the end of the first conductive layer formation step. The firing step was started one hour after the end of the second conductive layer formation step.

The thicknesses of the conductive layers 14 in the conductive layer-attached resin base materials 1 of Examples 4 to 6 were 26.5 μm, 24.4 μm, and 22.2 μm, respectively.

### Example 7

A conductive layer-attached resin base material 1 was obtained in a similar manner to Example 4 under the same conditions as in Example 4 except that the following roughening step was performed instead of the roughening step of Example 4.

In Example 7, the surface 12A of the insulating resin base material 12 was subjected to roughening treatment by dry treatment based on a microwave plasma system. As conditions for the dry treatment based on a microwave plasma system, the CF4 flow rate ratio was set to 13%, and the amount of etching was set to 1.0 μm.

The thickness of the conductive layer 14 in the conductive layer-attached resin base material 1 of Example 7 was 26.5 μm.

### (Evaluation)

The adhesion strength between the insulating resin base material 12 and the conductive layer 14 was evaluated for each of the conductive layer-attached resin base materials 1 of Examples 1 to 7 and the comparative conductive layer-attached resin base materials of Comparative Examples 1 to 4 produced through the above steps.

A 90° peel test was used for the evaluation of the adhesion strength. In the 90° peel test, the 90° peel strength (N/cm) was measured at a tensile speed of 50 mm/min by using an adhesion test machine (manufactured by Toyo Seiki Seisaku-sho, Ltd., Strograph, E2-L05) conforming to JIS C 6481 (1996, Test methods of copper-clad laminate for printed wiring boards). In the 90° peel test, a sample obtained by cutting each of the conductive layer-attached resin base materials 1 of Examples 1 to 7 and the comparative conductive layer-attached resin base materials of Comparative Examples 1 to 4 into a width of 10 mm and a length of 100 mm was used. At the time of the 90° peel test, a cut of 5 mm was made with a single blade from an end portion of each sample at the boundary portion between the conductive layer 14 and the insulating resin base material 12, and the peelability (adhesion strength) of the conductive layer 14 from the insulating resin base material 12 was evaluated with the peel angle of the conductive layer 14 with respect to the insulating resin base material 12 set to 90°. The evaluation results are shown in Table 1.

TABLE 1

| | | | Evaluation |
|---|---|---|---|
| | Insulating resin | | 90° peel test |
| | material | Blasting step | [N/cm] |
| Example 1 | Base material A | Dry ice blasting | 2.79 |
| Example 2 | Base material A | Dry ice blasting | 2.85 |
| Comparative | Base material A | — | 1.65 |
| example 1 | | | |
| Comparative | Base material A | — | 1.80 |
| example 2 | | | |
| Example 3 | Base material A | Dry ice blasting | 5.60 |
| Comparative | Base material A | — | 1.47 |
| example 3 | | | |
| Comparative | Base material A | — | 1.77 |
| example 4 | | | |
| Example 4 | Base material B | Dry ice blasting | 4.65 |
| | | (weak) | |
| Example 5 | Base material B | Dry ice blasting | 3.90 |
| | | (standard) | |
| Example 6 | Base material B | Dry ice blasting | 3.20 |
| | | (medium) | |
| Example 7 | Base material B | Dry ice blasting | 4.50 |

As shown in Table 1, the conductive layer-attached resin base materials 1 of Examples 1 and 2, which were each produced through a process including a blasting step, achieved improvements in adhesion strength as compared to the comparative conductive layer-attached resin base materials of Comparative Examples 1 and 2, which were each produced under the same conditions except that a blasting step was not performed. Further, the conductive layer-attached resin base material 1 of Example 3, which was produced through a process including a blasting step, achieved an improvement in adhesion strength as compared to the comparative conductive layer-attached resin base materials of Comparative Examples 3 and 4, which were each produced under the same conditions except that a blasting step was not performed. Further, the conductive layer-attached resin base materials 1 of Examples 4 to 7, which were each produced through a process including a blasting step, achieved improvements in adhesion strength as compared to the comparative conductive layer-attached resin base materials of Comparative Examples 1 to 4, in which a blasting step was not performed.

The peel strength was high when the nozzle pressure of dry ice blasting was 0.3 MPa or more and 0.7 MPa or less.

Further, the conductive layer-attached resin base materials 1 of Examples 1 to 7 were obtained through one step as a blasting step, and thus achieved shortening of the process as compared to a conventional technology in which minute foreign matters are removed by a plurality of steps.

Thus, it has been revealed that the present Examples can achieve improvements in adhesion strength between the insulating resin base material 12 and the conductive layer 14 and shortening of the process as compared to the Comparative Examples and the conventional technology.

### EXPLANATIONS OF LETTERS OR NUMERALS

1 CONDUCTIVE LAYER-ATTACHED RESIN BASE MATERIAL
12 INSULATING RESIN BASE MATERIAL
14 CONDUCTIVE LAYER
16 FIRST CONDUCTIVE LAYER
18 SECOND CONDUCTIVE LAYER

1. A method for forming a conductive layer-attached resin base material, the method comprising:
a roughening step of performing roughening treatment on a surface of an insulating resin base material;
a blasting step of performing blast treatment on the surface of the insulating resin base material on which the roughening treatment has been performed, by dry blasting;
a modification step of performing surface modification on the surface of the insulating resin base material on which the blast treatment has been performed;
a first conductive layer formation step of forming a first conductive layer on the insulating resin base material on which the surface modification has been performed; and
a second conductive layer formation step of forming a second conductive layer on the first conductive layer by a wet film formation process.

2. The method for forming the conductive layer-attached resin base material according to claim 1, wherein
the roughening step
comprises a step of performing the roughening treatment on the surface of the insulating resin base material by plasma treatment, ultraviolet irradiation, chromic acid etching, permanganic acid etching, or organic solvent etching.

3. The method for forming the conductive layer-attached resin base material according to claim 2, wherein
the plasma treatment
comprises dry treatment based on a microwave plasma system or dry treatment based on a heat assist system.

4. The method for forming the conductive layer-attached resin base material according to claim 1, wherein
the blasting step
performs blast treatment on the surface of the insulating resin base material on which the roughening treatment has been performed, by the dry blasting that is dry ice blasting.

5. The method for forming the conductive layer-attached resin base material according to claim 4, wherein
a nozzle pressure of the dry ice blasting is 0.3 MPa or more and 0.7 MPa or less.

6. The method for forming the conductive layer-attached resin base material according to claim 1, wherein
the insulating resin base material contains filler.

7. The method for forming the conductive layer-attached resin base material according to claim 1, wherein
the modification step
performs surface modification on the surface of the insulating resin base material by plasma treatment, ultraviolet irradiation treatment, UV ozone treatment, or electrolytic sulfuric acid treatment.

8. The method for forming the conductive layer-attached resin base material according to claim 1, wherein
the modification step
performs surface modification on the surface of the insulating resin base material by
a first plasma treatment with an oxidizing gas containing 95% or more oxygen and
a second plasma treatment with a reducing gas containing 1% or more H₂ gas after the first plasma treatment.

9. The method for forming the conductive layer-attached resin base material according to claim 1, wherein
the first conductive layer formation step
forms the first conductive layer on the surface of the insulating resin base material on which the surface modification has been performed, by a dry film formation process.

10. The method for forming the conductive layer-attached resin base material according to claim 1, wherein
the first conductive layer and the second conductive layer are formed of the same metal.

11. The method for forming the conductive layer-attached resin base material according to claim 1, wherein
the modification step performs plasma treatment, the first conductive layer formation step performs sputtering, the insulating resin base material is placed in a chamber, and the modification step and the first conductive layer formation step are continuously performed without exposing the insulating resin base material to an atmosphere.

12. The method for forming the conductive layer-attached resin base material according to claim 1, comprising:
a firing step of heating a stacked body at a temperature lower than a glass transition point of the insulating resin base material, the stacked body being formed through the roughening step, the blasting step, the modification step, the first conductive layer formation step, and the second conductive layer formation step in this order.
